(19) United States
(12) Patent Application Publication
(10) Pub. No.: US 2008/0092812 A1
(43) Pub. Date: Apr. 24, 2008

(54) Methods and Apparatuses for Depositing Uniform Layers

(76) Inventors: James McDiarmid, Dana Point, CA (US); Ronald L. Colvin, Gilbert, AZ (US); John W. Rose, Cave Creek, AZ (US); Earl Blake Samuels, Scottsdale, AZ (US)

Correspondence Address: LARRY WILLIAMS, 3645 MONTGOMERY DR, SANTA ROSA, CA, 95405-5212, US

(21) Appl. No.: 11/628,925

(22) PCT Filed: Jun. 10, 2005
(86) PCT No.: PCT/US05/20436

§ 371 Date: Jan. 8, 2007

Related U.S. Application Data
(60) Provisional application No. 60/578,935, filed on Jun. 10, 2004.

(51) Int. Cl. C23C 16/52; H01L 21/36

(52) U.S. Cl. 118/695; 118/715; 118/724; 118/730; 438/478; 257/E21.461

(57) ABSTRACT

An apparatus including a process chamber and a gas flow control system for depositing layers having uniform properties on substrates.

### CROSS-REFERENCE TO RELATED APPLICATIONS

The present application claims benefit of U.S. Provisional Patent Application Ser. No. 60/578,935, filed 10 Jun. 2004. The present application is related to U.S. Pat. No. 6,331,212, filed 17 Apr. 2000 and U.S. Pat. No. 6,774,060, filed 7 Jul. 2001. The contents of all of these applications are incorporated herein in their entirety by this reference.

### BACKGROUND

This invention relates to improved methods and apparatus for thermally processing workpieces; more particularly, the deposition of layers for electronic devices and optical-electronic devices.

High temperature processing of semiconductor wafers is essential to modern microelectronic device manufacturing. These processes include processes such as chemical vapor deposition (CVD), silicon epitaxy, silicon germanium, and compound semiconductor epitaxy. These processes are typically performed at temperatures ranging from about 400 to 1200 degrees Celsius. Numerous standard textbooks and references exist that described elevated temperature processing of semiconductor wafers.

Advanced silicon devices require line widths of less than one micron, and junction depths as small as 25 angstroms. In addition, large wafers, such as 300 mm wafers and larger, have a reduced thermal budget cycle, thus the temperature processing time must be reduced to limit lateral and downward dopant diffusion to meet the required thermal budget cycle. Furthermore, the requirements for thickness uniformity and dopant uniformity for epitaxial layers of silicon as well as for other semiconductors are becoming increasingly more stringent.

There are numerous applications requiring methods and apparatus for depositing layers having high thickness uniformity and high composition uniformity in addition to other properties and/or performance capabilities needed for fabricating products such as electronic devices and optical-electronic devices.

### SUMMARY

This invention seeks to provide methods and apparatus that can overcome one or more deficiencies in methods and apparatus for processes used for forming layers of materials that require high thickness uniformity and high composition uniformity such as those required for depositing doped layers and processes such as depositing layers of compound materials.

It is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

The above and still further features and advantages of the present invention will become apparent upon consideration of the following detailed descriptions of specific embodiments thereof, especially when taken in conjunction with the accompanying drawings.

### DESCRIPTION OF THE DRAWINGS

FIG. 1 is a cross-section top view of an embodiment of the present invention.

FIG. 2A is a cross-section side view of the embodiment shown in FIG. 1.

FIG. 2B is a cross-section side view of another embodiment of the apparatus shown in FIG. 2A.

FIG. 3 is a cross-section top view of another embodiment of the present invention.

FIG. 4A is a cross-section side view of the apparatus shown in FIG. 3.

FIG. 4B is a cross-section side view of another embodiment of the apparatus shown in FIG. 4A.

FIG. 5 is a cross-section top view of another embodiment of the present invention.

FIG. 6A is a cross-section side view of another embodiment of the present invention.

FIG. 6B is a cross-section side view of another embodiment of the present invention.

FIG. 7 is a cross-section top view of another embodiment of the present invention.

FIG. 8 is a cross-section top view of an embodiment of the present invention.

FIG. 9A is a cross-section side view of an embodiment of the present invention.

FIG. 9B is a cross-section side view of an embodiment of the present invention.

FIG. 9C is a cross-section side view of an embodiment of the present invention.

FIG. 10 is a top view of a velocity gradient plate according one embodiment of the present invention.

FIG. 10A is a cross-section side view of the velocity gradient plate of FIG. 10.

FIG. 11 shows thickness uniformity data.

FIG. 12 shows resistivity uniformity data.

FIG. 13 an enlarged view of a gas injector according one embodiment of the present invention.

FIG. 14 is a cross-section side view of an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION

The operation of embodiments of the present invention will be discussed below in the context of the deposition of an epitaxial layer of doped silicon on a silicon wafer. It is to be understood, however, that embodiments in accordance with the present invention may be used to perform essentially any substrate-processing step requiring layer thickness uniformity and composition uniformity across the substrate. As examples, embodiments of the present invention can be configured for depositing layers of materials such as gallium nitride, gallium arsenide, silicon germanium; gallium aluminum arsenide, indium phosphide, cadmium telluride, mercury cadmium telluride, silicon carbide, silicon nitride, doped silicon oxide, BPSG, PSG and others.

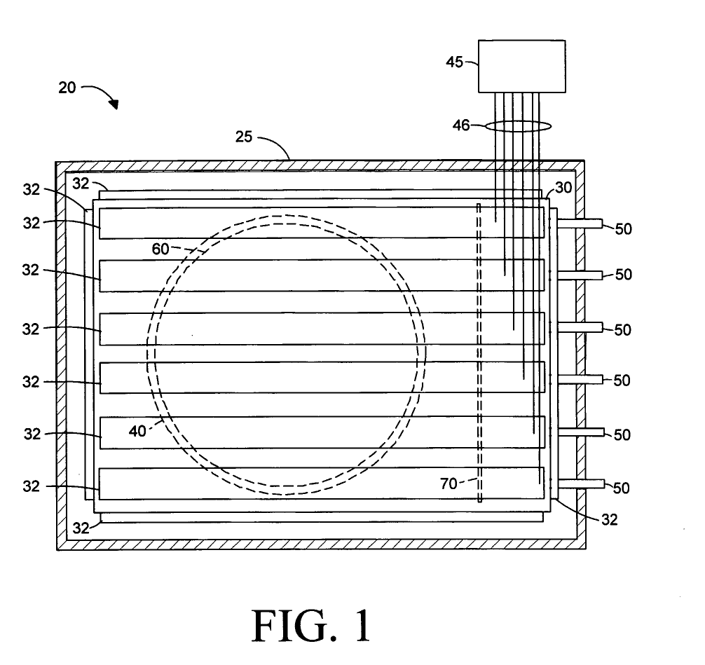

Reference is now made to FIG. 1 wherein there is shown a top view of one embodiment of an apparatus 20 for thermally processing workpieces such as substrates and such as semiconductor wafers. Apparatus 20 includes a housing 25 shown in a cross section top view and a process chamber 30 disposed substantially within housing 25. In other words, process chamber 30 is mounted in housing 25. The top of housing 25 is removed to show process chamber 30 in housing 25. Process chamber 30 also includes a susceptor 40 (shown in dashed lines) held substantially within process chamber 30. Susceptor 40 has a substrate or wafer holding surface.

A preferred embodiment includes a plurality of electric powered heating elements 32 disposed between housing 25 and process chamber 30 for heating process chamber 30. FIG. 1 shows heating elements 32 arranged along the top surfaces and side surfaces of process chamber 30. Heating elements 32 may also be arranged along the bottom surfaces of process chamber 30; for the sake of clarity, heating elements 32 are not shown along the bottom surfaces in FIG. 1. Examples of the types of heating elements that are suitable for heating elements 32 include electrical resistance strip heaters, IR lamps, RF power induction heaters, and arc lamps.

In a preferred embodiment, the electrical resistance strip heaters are silicon carbide coated graphite strip heaters. Examples of embodiments of the present invention that use strip heaters include one embodiment in which the strip heaters are near the surface of process chamber 30 but without direct physical contact.

Apparatus 20 further includes a temperature control system 45 that controls power delivered to heating elements 32. A preferred embodiment of temperature control system 45 includes a plurality of temperature sensors. The temperature sensors are arranged so as to derive temperature information for temperature control system 45. Preferred locations for measuring temperatures for temperature control system 45 include process chamber 30, heating elements 32, and wafer 60. Temperature control system 45 is configured to be responsive to temperature information from the temperature sensors so as to allow independent control of the temperature of each heating element 32. Standard temperature sensors that can be used in semiconductor processing are usable for embodiments of the present invention. Some examples of temperature sensors that can be used include thermocouples, pyrometers, and thermometers.

Temperature control system 45 is coupled with heating elements 32 as stated above. Lines 46 are drawn to indicate the connections between temperature control system 45 and heating elements 32. In order to avoid confusion, the embodiment of the present invention presented in FIG. 1 only shows temperature control system 45 connected with heating elements 32 located over the top of process chamber 30. In other words, the connections with the remaining heating elements 32 are not shown for the sake of clarity. The heating elements 32 located over the top of process chamber 30 are placed so as to allow substantially independent temperature control for selected areas of the top surface of process chamber 30. Heating elements 32 placed near the bottom surface of process chamber 30 are similarly positioned so as to allow substantially independent temperature control for selected areas of the bottom surface of process chamber 30.

Process chamber 30 further includes a plurality of gas injectors 50 for flowing gas into process chamber 30. Gas injectors 50 are configured so that they can be connected with a gas supply. For the purpose of illustration, a semiconductor wafer 60 (drawn with dashed lines) is shown placed on susceptor 40. In a preferred embodiment, process chamber 30 includes a baffle 70 (drawn with dashed lines) for directing the flow of gas from gas injectors 50. Baffle 70 may comprise a substantially rigid solid such as a solid plate of a refractory material that is substantially inert to the process gases. Baffle 70 is disposed in front of the plurality of gas injectors so that gases from the injectors impinge on the baffle before reaching the susceptor. As an option, baffle 70 is positioned so as to be substantially perpendicular to the wafer holding surface and to the direction of gas flow. Baffle 70 is sized so as to allow gas to flow around baffle 70 after at least a portion of the gas impinges on baffle 70. In some embodiments, baffle 70 is removable so that process chamber 30 can be used with or without baffle 70. In another embodiment, baffle 70 and process chamber 30 are configured so baffle 70 is movable so as to allow baffle 70 to be positioned closer to or further from gas injectors 50.

In some embodiments, housing 25 includes construction materials such as ceramics, quartz, aluminum alloys, and iron alloys such as stainless steel. In a preferred embodiment, housing 25 is configured for active cooling. In one embodiment, housing 25 has walls forming coolant conduits 50 for carrying coolant. In an alternative embodiment, housing 25 includes cooling coils (not shown). The cooling coils contact the surface of housing 25 so as to be capable of removing heat when there is a coolant flow through the coils.

In preferred embodiments, process chamber 30 is configured as a hot wall process chamber so as to maintain wafer 60 at a substantially isothermal temperature. One example of a suitable process chamber and an example of a suitable housing is described in U.S. Pat. No. 6,331,212, filed 17 Apr. 2000, which is incorporated herein in its entirety by this reference.

Preferably, process chamber 30 is constructed of a thermally refractory material such as those commonly used for high temperature process equipment. Examples of suitable materials include silicon carbide, silicon carbide coated graphite, graphite, quartz, silicon, aluminum nitride, aluminum oxide, silicon nitride, magnesium oxide, zirconium oxide, and ceramics.

Some embodiments of process chamber 30 also have susceptor 40 rotatably coupled so that wafer 60 can be rotated during processing. Susceptor 40 is connected with process chamber 30 so as to allow rotation of susceptor 40 and to allow rotation of wafer 60 when supported on susceptor 40. Susceptor 40 is arranged so as to allow rotation of the wafer during processing. Specifically, susceptor 40 is coupled with process chamber 30 so as to allow rotation of the wafer support. A motor or other rotary motion source (not shown in FIG. 1) is rotatably coupled to susceptor 40 so as to cause rotation of susceptor 40.

Gas enters process chamber 30 from gas injectors 50, flow over wafer 60, and exits through an exhaust port 35 on the opposite side of process chamber 30. In preferred embodiments, exhaust port 35 is connected with a gas exit conduit (gas exit conduit not shown in FIG. 1). Preferably, gas injectors 50 comprise a plurality of individual gas injectors directing a gas flow to a selected area over the wafer holder surface and parallel to the wafer holder surface.

More preferably, gas injectors 50 comprise individual gas injectors directing a gas flow to a selected area over the wafer holder surface and substantially parallel to the wafer holder surface. The apparatus further includes a gas flow control system comprising a plurality of mass flow controllers wherein each of the individual gas injectors is connected with at least one dedicated mass flow controller so that each gas injector is capable of providing an independently controlled gas flow rate (gas flow control system not shown in FIG. 1). In some embodiments, apparatus 20 further comprises a gas flow control system comprising a plurality of mass flow controllers wherein each of the individual gas injectors is connected with at least one dedicated mass flow controller so that each gas injector is capable of providing an independently controlled gas flow rate and an independently controlled inlet gas composition.

In preferred embodiments of apparatus 20, the process chamber is configured to function as a hot wall process chamber, and more preferably as a substantially isothermal hot wall process chamber. For applications such as semiconductor epitaxy, the process chamber and substrate holder are configured to maintain the substrate at a substantially isothermal temperature during processing.

For the embodiment shown in FIG. 1, gas injectors 50 include multiple alternating pairs of gas injectors. For each pair of gas injectors, one injector is configured to provide a flow mixture of hydrogen plus a silicon source and an optional dopant; the second injector is configured to provide a flow mixture of hydrogen plus a dopant. The silicon source may be a silicon compound such as silane, monochlorosilane, dichlorosilane, trichlorosilane, and tetrachlorosilane. The dopant can be any of the commonly used dopants used for doping silicon such as compounds of boron and compounds of phosphorus.

The embodiment shown in FIG. 1 includes three pairs of injectors 50 spaced so as to provide a substantially even flow across the surface of the wafer. Preferably, the two injectors in each pair are closely spaced. The pairs of injectors are positioned so as to provide a spatially distributed flow of gas in a plane substantially parallel to the wafer holding surface of the susceptor. The susceptor is disposed between the plurality of gas injectors and the gas exhaust port. The plurality of gas injectors is positioned along the edge of the wafer holding surface with each of the gas injectors spaced so that each of the gas injectors provides a flow directed toward a specified region of the area above the wafer holding surface. The embodiment shown in FIG. 1 also includes a gas flow control system (not shown in FIG. 1). The gas flow control system includes gas flow conduits, valves, and mass flow controllers so that the mass flows for each of the gases provided to process chamber 30 can be independently controlled. Optionally, the flow of dissimilar gases can be independently controlled for some embodiments of the present invention.

For some embodiments of the present invention, the flow rate of hydrogen plus silicon source for one of the injectors of an injector pair can be controlled independently of the flow rate of hydrogen plus dopant flow through the second injector of the injector pair. This configuration means that the amount of silicon source that can be provided to different regions of the wafer can be independently controlled, and the amount of dopant that can be provided to different regions of the wafer can be independently controlled. This further means that the growth rate of the silicon for different regions of the wafer can be controlled by adjusting the flow rate of the silicon source, and the amount of dopant incorporated in different regions of the wafer can be controlled by adjusting the flow rate of the dopant.

In another embodiment of the present invention, the gas flow control system is configured so that the mass flow rates for the silicon source, the mass flow rates for the dopant, and the mass flow rates for the hydrogen can each be independently controlled. This further means that the growth rate of the silicon for different regions of the wafer can be controlled by adjusting the flow rate of the silicon source, the amount of dopant incorporated in different regions of the wafer can be controlled by adjusting the flow rate of the dopant, and the amount of hydrogen for different regions of the wafer can be controlled by adjusting the flow rate of the hydrogen. In a more preferred embodiment, the flow rate of each of the gases can be adjusted without affecting the flow rate of either of the other gases.

As indicated above, one of the pair of injectors is configured to flow a mixture of hydrogen and silicon source. As an option, the configuration may also include flowing dopant with the mixture of hydrogen and silicon source. The decision to include dopant with the silicon source may depend on a variety of factors such as the requirements for the deposited layer in terms of dopant levels; alternatively, it may be a matter of designer choice.

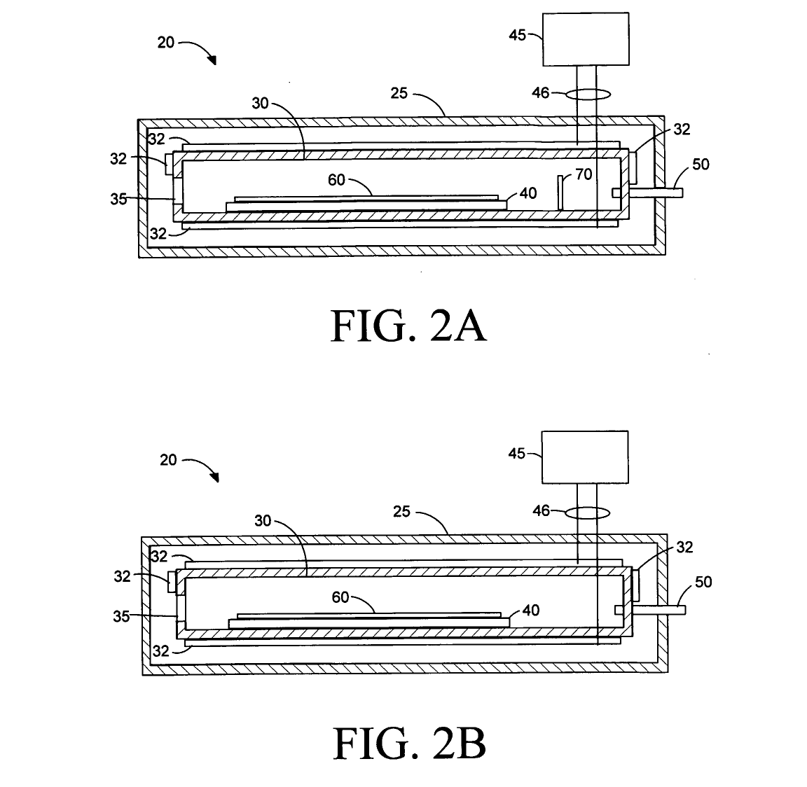

Reference is now made to FIG. 2A where there is shown a cross-section side view of the embodiment described in FIG. 1. FIG. 2A shows housing 25 with the top present and a sidewall removed to show a side view of the interior of housing 25. Process chamber 30 is shown with the top present and a sidewall removed to show a side view of the interior of process chamber 30. Heating elements 32 are shown contacting the top, the sides, and the bottom of process chamber 30. Process chamber 30 includes susceptor 40 and a plurality of gas injectors 50 (only one shown in FIG. 2A). FIG. 2A also shows a wafer 60 placed on susceptor 40. As an option, some embodiments of susceptor 40 include having a recessed area for holding wafer 60. Baffle 70 is also shown in FIG. 2A.

FIG. 2A also shows temperature control system 45 that controls power delivered to heating elements 32. Temperature control system 45 is coupled with heating elements 32 as stated above. Lines 46 are drawn to indicate the connections between temperature control system 45 and heating elements 32. In order to avoid confusion, the embodiment of the present invention presented in FIG. 2A only shows temperature control system 45 connected with heating elements 32 located on the top of process chamber 30 and on the bottom of process chamber 30. In other words, the connections with the remaining heating elements 32 are not shown for the sake of clarity.

The embodiment shown in FIG. 2A also includes a gas flow control system (not shown in FIG. 2A) that is essentially the same as that described for the embodiment shown in FIG. 1. The gas flow control system includes gas flow conduits, valves, and mass flow controllers so that the mass flows for each of the gases provided to process chamber 30 can be independently controlled.

As stated above, use of baffle 70 is optional; some embodiments of the present invention do not include the baffle. Reference is now made to FIG. 2B where there is shown a cross-section side view of another embodiment of the present invention that does not include a baffle. The embodiment shown in FIG. 2B is substantially the same as that described for FIG. 1 and FIG. 2A with the exception that baffle 70 is not included.

Each gas injector 50 is placed so that flow from the gas injector is directed to a specified area of the wafer. In one embodiment of the present invention, each gas injector 50 is configured to receive a flow mixture of hydrogen plus silicon source plus optional dopant and a flow mixture of hydrogen plus dopant. The embodiment shown in FIG. 2B also includes a gas flow control system (not shown in FIG. 2B). The gas flow control system includes gas flow conduits, valves, and mass flow controllers so that the mass flows for each of the gases provided to process chamber 30 can be independently controlled. Although the two flow mixtures used for different areas of the wafer enter process chamber 30 through the same gas injector, the flow rates for each flow mixture are independently controlled.

The embodiment shown in FIG. 2B has a configuration such that the amount of silicon source that can be provided to different regions of the wafer can be independently controlled and the amount of dopant that can be provided to different regions of the wafer can be independently controlled. This further means that the growth rate of the silicon for different regions of the wafer can be controlled by adjusting the flow rate of the silicon source, and the amount of dopant incorporated in different regions of the wafer can be controlled by adjusting the flow rate of the dopant.

In another embodiment of the present invention, the gas flow control system is configured so that the mass flow rates for the silicon source, the mass flow rates for the dopant, and the mass flow rates for the hydrogen can each be independently controlled. This further means that the growth rate of the silicon for different regions of the water can be controlled by adjusting the flow rate of the silicon source, the amount of dopant incorporated in different regions of the wafer can be controlled by adjusting the flow rate of the dopant, and the amount of hydrogen for different regions of the wafer can be controlled by adjusting the flow rate of the hydrogen. In a more preferred embodiment, the flow rate of each of the gases can be adjusted without affecting the flow rate of either of the other gases.

Preferred embodiments of the present invention include having heating elements 32 disposed about process chamber 30 so as to allow substantially independent temperature control of different areas of the process chamber. The substantially independent temperature control of the process chamber surface above the wafer is particularly important for some embodiments of the present invention. More preferably, the heating elements are placed and the temperature control system is configured so as to allow substantially independent control of the temperatures of the specified region of the area above the wafer holding surface for each of the gas injectors. As a result of having the process chamber enclosing the wafer, the temperature of the wafer is also determined by controlling the temperatures of the process chamber surfaces.

In a preferred embodiment, the temperature control system is configured for substantially independent control of the temperature of different regions of the process chamber surface. As an option, the temperature control system is configured for substantially independent control of the temperature of each of the heating elements, so as to control the temperatures of different regions of the process chamber surface. As another option, the temperature control system includes a plurality of temperature sensors. The temperature sensors are placed so as to provide temperature measurements for controlling the temperatures of different regions of the process chamber surface. For another embodiment of the present invention, the temperature control system comprises a plurality of temperature sensors, and the temperature sensors are placed so as to provide temperature measurements for controlling the temperatures of each of the heating elements.

For the most preferred embodiment, the distribution of the gases, both in terms of flow rate and concentrations are independently controlled to different areas above the wafer. In addition, the arrangement of the heating elements and the configuration of the temperature controller provide substantially independent temperature control of the surfaces of the process chamber in relation to the distribution of gases over the surface of the wafer. In other words, the composition, the flow rates, and the distribution of the gases above different areas of the wafer are controlled in addition to control of the temperatures to which the gases flowing above the wafer are exposed. The temperature distribution, the gas distribution, the gas flow rates, and the gas composition are all coordinated so as to provide a uniform composition profile and uniform thickness profile for layers deposited on the substrate.

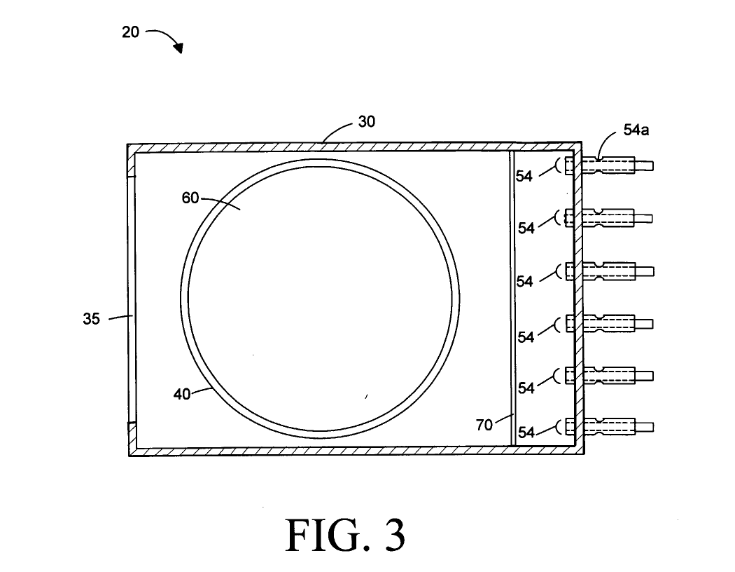

Reference is now made to FIG. 3, where there is shown a cross-section top view of one embodiment of an apparatus 20 for thermally processing workpieces such as semiconductor wafers. Apparatus 20 includes a housing (not shown in FIG. 3), heating elements (not shown in FIG. 3), and a process chamber 30, all substantially the same as that described for the embodiments shown in FIG. 1, FIG. 2A and FIG. 2B. The top of process chamber 30 is removed to show the interior of process chamber 30. Process chamber 30 also includes a susceptor 40 and a plurality of gas injectors 54 for flowing gas in to process chamber 30. For the purpose of illustration, a semiconductor wafer 60 is shown placed on susceptor 40. In a preferred embodiment, process chamber 30 includes a baffle 70 for directing the flow of gas from gas injectors 54. In some embodiments, baffle 70 is removable so that process chamber 30 can be used with or without baffle 70.

For the embodiment of FIG. 3, the gas flow path is from gas injectors 54 through process chamber 30. The gas enters from gas injectors 54, flows over wafer 60, and exits through an exhaust port 35 on the opposite side of process chamber 30.

For the embodiment shown in FIG. 3, each gas injector 54 includes concentric gas flow conduits such as gas flow tubes with an inner tube for carrying an inner gas flow mixture and an outer tube for carrying an outer gas flow mixture. For each gas injector 54, one of the tubes is configured to provide a flow mixture of hydrogen plus a silicon source and an optional dopant; the second tube is configured to provide a flow mixture of hydrogen plus a dopant. FIG. 3 shows a preferred embodiment that is configured so that the inner tube is configured to provide the flow mixture of hydrogen plus the silicon source and the optional dopant; the outer tube is configured to provide the flow mixture of hydrogen plus the dopant. The silicon source and dopant are compounds such as those described above.

The embodiment shown in FIG. 3 shows six injectors 54 spaced so as to provide a substantially even flow across the surface of the wafer; each injector 54 provides gas to a different area of the wafer so that the entire surface of the wafer receives a gas flow stream. The embodiment shown in FIG. 3 also includes a gas flow control system (not shown in FIG. 3). The gas flow control system includes gas flow conduits, valves, and mass flow controllers so that the mass flows for each of the gases provided to process chamber 30 can be independently controlled. The gas injectors are positioned so as to provide a spatially distributed flow of gas in a plane substantially parallel to the wafer holding surface of the susceptor. The susceptor is disposed between the plurality of gas injectors and the gas exhaust port. The plurality of gas injectors is positioned along the edge of the wafer holding surface with each of the gas injectors spaced so that each of the gas injectors provides a flow directed toward a specified region of the area above the wafer holding surface.

For some embodiments of the present invention, the flow rate of hydrogen plus silicon source can be controlled independently of the flow rate of hydrogen plus dopant flow for each injector 54. This configuration means that the amount of silicon source that can be provided to different regions of the wafer can be independently controlled and the amount of dopant that can be provided to different regions of the wafer can be independently controlled. This further means that the growth rate of the silicon for different regions of the wafer can be controlled by adjusting the flow rate of the silicon source for that region of the wafer, and the amount of dopant incorporated in different regions of the wafer can be controlled by adjusting the flow rate of the dopant for that region of the wafer.

In another embodiment of the present invention, the gas flow control system is configured so that the mass flow rates for the silicon source, the mass flow rates for the dopant, and the mass flow rates for the hydrogen can each be independently controlled. This further means that the growth rate of the silicon for different regions of the wafer can be controlled by adjusting the flow rate of the silicon source, the amount of dopant incorporated in different regions of the wafer can be controlled by adjusting the flow rate of the dopant for different regions of the wafer, and the amount of hydrogen for different regions of the wafer can be controlled by adjusting the flow rate of the hydrogen for different regions of the wafer. In a more preferred embodiment, the flow rate of each of the gases can be adjusted without affecting the flow rate of either of the other gases.

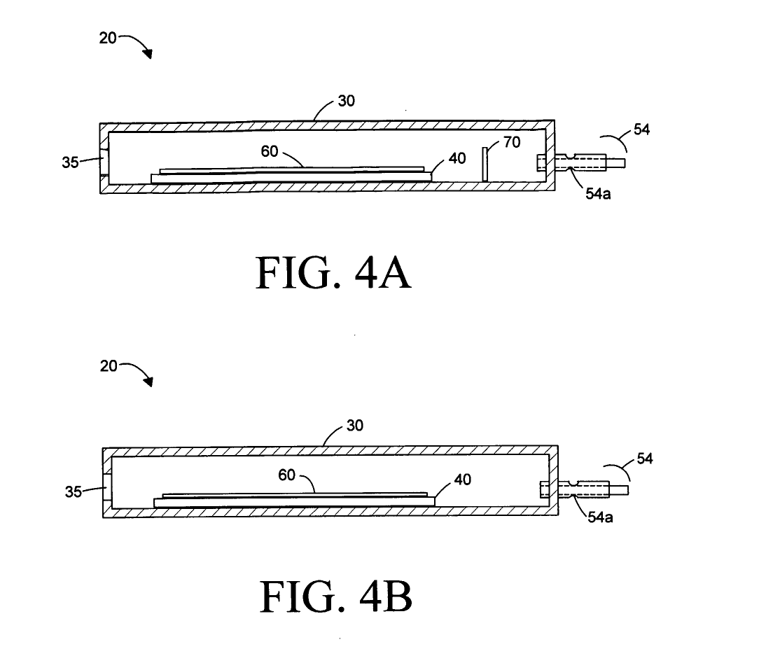

Preferably, the concentric tubes of injectors 54 are rigid tubes such as those typically used for deposition processes. The tubes are typically made of materials such as quartz, silicon carbide, and silicon carbide coated graphite; in other words, materials that are substantially inert chemically and thermally stable for the deposition process conditions. For the embodiment shown in FIG. 3, the tubes are mechanically held so that the openings for each of the tubes remain concentric. A variety of methods can be used for holding the tubes concentrically. For the embodiment shown in FIG. 3, dimples 54a are formed in the surface of the outer tube so as to make contact with the inner tube at three substantially equally spaced points around the circumference of the inner tube. The points of contact at dimples 54a are made so that they are sufficiently small so as to not significantly disrupt the flow between the inner tube wall and the outer tube wall. FIG. 4A shows a side view of the embodiment shown in FIG. 3 and provides a more detailed view of dimples 54a.

Reference is now made to FIG. 4B where there is shown a cross-section side view of another embodiment of the present invention. The embodiment shown in FIG. 4B is substantially the same as that shown in FIG. 4A with the exception that the embodiment shown in FIG. 4B does not include a baffle 70.

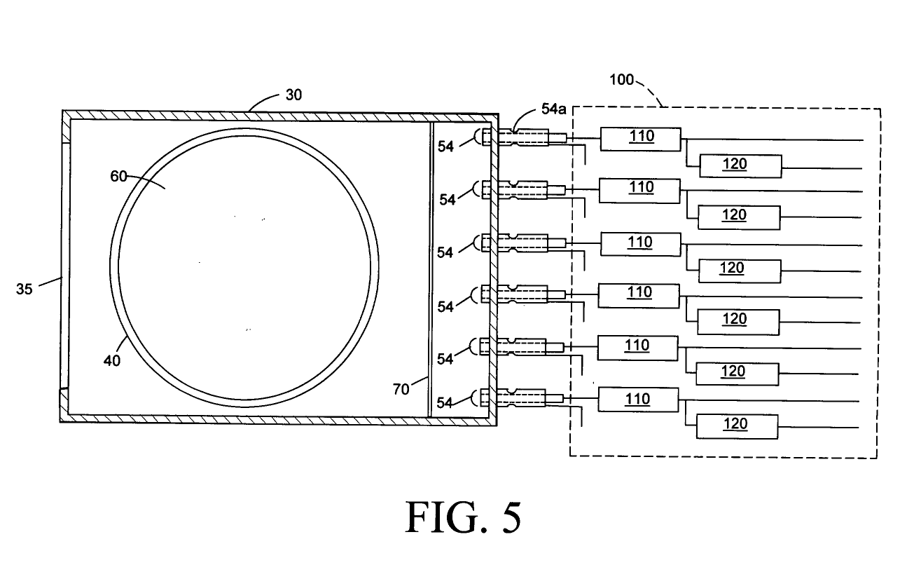

Next, embodiments of the gas flow control system will be described in more detail. Reference is now made to FIG. 5 where there is shown an embodiment of the present invention that is essentially the same as that presented in FIG. 3. The embodiment shown in FIG. 5 includes a housing (not shown in FIG. 5), heating elements (not shown in FIG. 5), and a process chamber 30, all substantially the same as that described for the embodiments shown in FIG. 1, FIG. 2A and FIG. 2B. The embodiment shown in FIG. 5 includes a process chamber 30 that is essentially the same as process chamber 30 in FIG. 3. FIG. 5 also shows a configuration of gas flow control system 100 according to one embodiment of the present invention. Details of process chamber 30 were presented in the description of FIG. 3 and will not be presented here.

Gas flow control system 100 is connected with gas injectors 54 so as to provide a controlled flow of selected gases to each of the injectors 54. FIG. 5 shows one of the injectors 54 connected with components of gas flow control system 100. The components include a mass flow controller 110 and a mass flow controller 120. Mass flow controllers suitable for embodiments of the present invention are commercially available from numerous vendors and are in common use. A common abbreviation for mass flow controller is “MFC.”

The configuration of gas flow control system 100 shown in FIG. 5 has MFC 120 controlling the flow of a gas mixture of hydrogen plus dopant that feeds into a flow of a gas mixture of silicon source plus hydrogen. The gas mixture from MFC 120 and the gas mixture of silicon source plus hydrogen are connected as input to MFC 110. MFC 110 has a fluid connection with the inner tube of one of the gas injectors 54 so that MFC 110 can control the flow rate of the gas mixture from MFC 120 and the gas mixture of silicon source plus hydrogen. Gas flow control system 100 also has a fluid connection with the outer tube of the gas injector 54 so as to provide a flow of hydrogen to the outer tube. As described above, each of the gas injectors 54 are disposed so as to provide a gas flow to a different area of a wafer 60 placed in process chamber 30. FIG. 5 shows an embodiment having six injectors. Each injector 54 has its own MFC 110 and MFC 120 connected as described above. This means that gas flow control system 100 shown in FIG. 5 includes six of the MFC 110 and six of the MFC 120 along with the necessary gas flow conduits for the connections as described above.

Gas flow control system 100 enables independent control of the flow of silicon source, dopant, and hydrogen to the different areas of wafer 60. Each of the areas of wafer 60 receiving flow from an injector 54 can receive the amount of silicon source, the amount of dopant, and the amount of hydrogen needed for that area so that the thickness uniformity and dopant uniformity across the wafer is optimized.

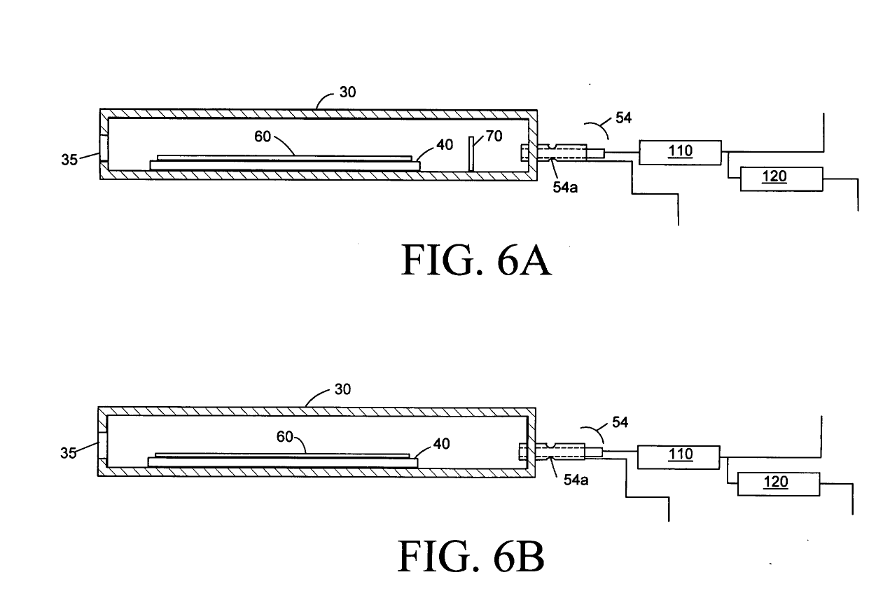

To further illustrate the embodiment described for FIG. 5, cross section side views of the interior of process chamber 30 are shown with gas flow control system 100 in FIG. 6A and FIG. 6B. The apparatus shown in FIG. 6A and FIG. 6B are essentially the same as that described for FIG. 5 with the exception that FIG. 6B shows an embodiment of process chamber 30 without a baffle.

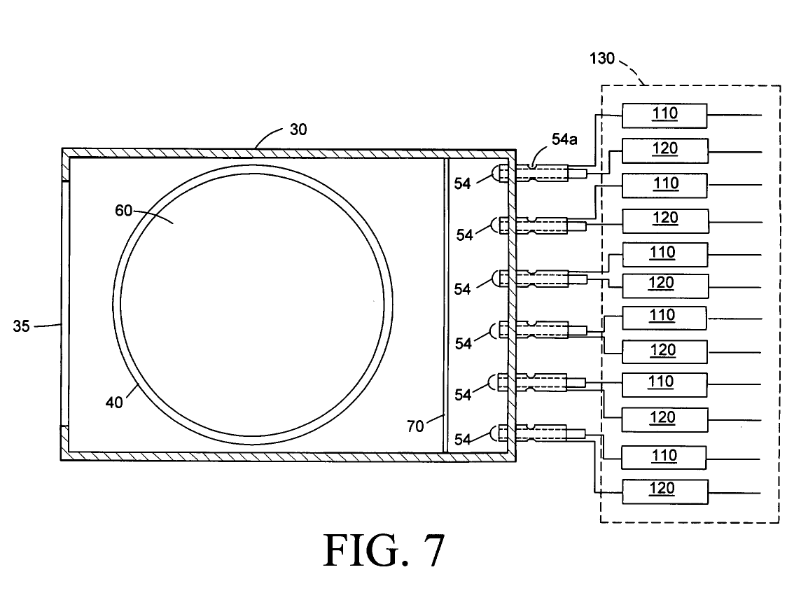

Reference is now made to FIG. 7 where there is shown an embodiment of the present invention that is essentially the same as that presented in FIG. 3. The embodiment shown in FIG. 7 includes a housing (not shown in FIG. 7), heating elements (not shown in FIG. 7), and a process chamber 30, all substantially the same as that described for the embodiments shown in FIG. 1, FIG. 2A and FIG. 2B. The embodiment shown in FIG. 7 includes a process chamber 30 that is essentially the same as process chamber 30 in FIG. 3. FIG. 7 also shows a configuration of gas flow control system 130 according to one embodiment of the present invention. Details of process chamber 30 were presented in the description of FIG. 3 and will not be presented here.

Gas flow control system 130 is connected with gas injectors 54 so as to provide a controlled flow of selected gases to each of the injectors 54. FIG. 7 shows one of the injectors 54 connected with components of gas flow control system 130. The components include a first mass flow controller such as a mass flow controller 110 and a second mass flow controller such as a mass flow controller 120.

The configuration of gas flow control system 130 shown in FIG. 7 has MFC 120 controlling the flow of a gas mixture of hydrogen plus dopant that feeds into a fluid connection with the outer tube of one of the gas injectors 54 so that MFC 120 can control the flow rate of the gas mixture of dopant plus hydrogen. Gas flow control system 130 also has a fluid connection with the inner tube of the gas injector 54 so as to provide a flow of a gas mixture of silicon source plus of hydrogen to the inner tube. As described above, each of the gas injectors 54 are disposed so as to provide a gas flow to a different area of wafer 60 placed in process chamber 30. FIG. 7 shows an embodiment having six injectors. Each injector 54 has its own MFC 110 and MFC 120 connected as described for the embodiment shown in FIG. 7. This means that gas flow control system 130 shown in FIG. 7 includes six of the MFC 110 and six of the MFC 120 along with the necessary gas flow conduits for the connections as described for the embodiment shown in FIG. 7.

Gas flow control system 130 enables independent control of the flow of silicon source, dopant, and hydrogen to the different areas of wafer 60. Each of the areas of wafer 60 receiving flow from an injector 54 can receive the amount of silicon source, the amount of dopant, and the amount of hydrogen needed for that area so that the thickness uniformity and dopant uniformity across the wafer is optimized.

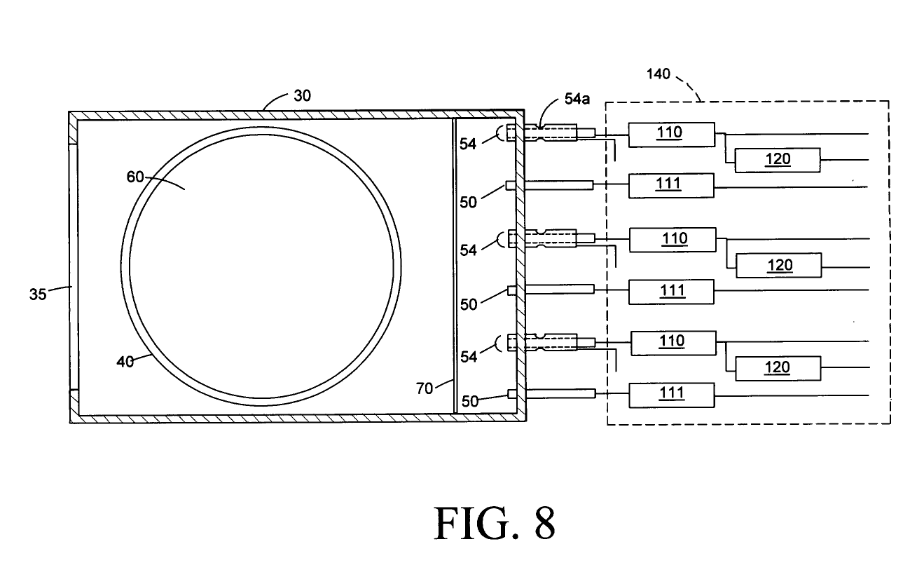

Reference is now made to FIG. 8 where there is shown an embodiment of the present invention that is essentially the same as that presented in FIG. 3. The embodiment shown in FIG. 8 includes a housing (not shown in FIG. 8), heating elements (not shown in FIG. 8), and a process chamber 30, all substantially the same as that described for the embodiments shown in FIG. 1, FIG. 2A and FIG. 2B. The embodiment shown in FIG. 8 includes a process chamber 30 that is essentially the same as process chamber 30 in FIG. 3, with the exception of having gas injectors 50 like the injectors 50 described for the embodiment shown in FIG. 1 and having gas injectors 54 that are essentially the same as the injectors 54 described for the embodiment shown in FIG. 3. The embodiment of FIG. 8 shows gas injectors 50 and gas injectors 54 in side-by-side alternating positions. FIG. 8 also shows a configuration of a gas flow control system 140 according to one embodiment of the present invention. Details of the housing, the heating elements, and process chamber 30 were presented in the description of FIG. 1; those details will not be repeated here.

Gas flow control system 140 is connected with gas injectors 50 and gas injectors 54 so as to provide a controlled flow of selected gases to each of the injectors 50 and injectors 54. FIG. 8 shows one of the injectors 50 connected with components of gas flow control system 140 and one of the injectors 54 connected with components of gas flow control system 140. The components connected to injectors 50 include a mass flow controller 111. The components connected to injectors 54 include a mass flow controller 110 and a mass flow controller 120.

Gas flow control system 140 is connected with gas injectors 54 so as to provide a controlled flow of selected gases to each of the injectors 54. FIG. 8 shows one of the injectors 54 connected with components of gas flow control system 140. The components include a mass flow controller 110 and a mass flow controller 120.

The configuration of gas flow control system 140 shown in FIG. 8 has MFC 120 controlling the flow of a gas mixture such as a mixture of hydrogen plus dopant that feeds into a flow of a gas mixture such as a mixture of silicon source plus hydrogen. The gas mixture from MFC 120 and the gas mixture of silicon source plus hydrogen are connected as input to MFC 110. MFC 110 has a fluid connection with the inner tube of one of the gas injectors 54 so that MFC 110 can control the flow rate of the gas mixture from MFC 120 and the gas mixture of silicon source plus hydrogen. Gas flow control system 140 also has a fluid connection with the outer tube of the gas injector 54 so as to provide a flow of hydrogen or other gas to the outer tube. As described above each gas injector 54 is disposed so as to provide a gas flow to a different area of a wafer 60 placed in process chamber 30. FIG. 8 shows an embodiment having three injectors 50 and three injectors 54. Each injector 54 has its own MFC 110 and MFC 120 connected as described above. This means that gas flow control system 140 shown in FIG. 8 includes three of the MFC 110 connected with injectors 54 and three of the MFC 120 connected with injectors 54 along with the necessary gas flow conduits for the connections. FIG. 8 does not show all of the mass flow controllers for the injectors 54. Gas flow control system 140 is also connected with each gas injector 50. Gas flow control system 140 includes a mass flow controller 111 for each gas injector 50, i.e., each injector 50 has its own MFC 111. This means that gas flow control system 140 includes three of the MFC 111 connected with injectors 50. FIG. 8 does not show all of the mass flow controllers for gas flow control system 140. The configuration of gas flow control system 140 shown in FIG. 8 has MFC 111 controlling the flow of a gas mixture such as a mixture of hydrogen plus dopant that feeds into gas injector 50. Each gas injector 50 is associated with one of the gas injectors 54 so that each of the gas injectors 50 and each of the associated gas injectors 54, in combination, are capable of providing independent control of the flow of silicon source, dopant, and hydrogen to the different areas of wafer 60. Each of the areas of wafer 60 receiving flow from an injector 50 and associated injector 54 can receive the amount of silicon source, the amount of dopant, and the amount of hydrogen needed for that area so that the thickness uniformity and dopant uniformity across the wafer are optimized.

For a preferred embodiment of the present invention, the process chamber is a hot wall substantially isothermal process chamber heated with a plurality of electrically powered heating elements disposed about the outside surfaces of the chamber. For example, the heating elements may be arranged along the top surfaces and bottom surfaces of process chamber 30. Heating elements may also be arranged along the side surfaces of process chamber 30. In a preferred embodiment, the electrical resistance strip heaters are silicon carbide coated graphite strip heaters. The strip heaters are placed so that they do not make direct contact with the process chamber. In other words, preferred embodiments of the present invention are configured so that there is a space or a dielectric material between the strip heaters and the surface of the process chamber. The strip heaters are commercially available and are used in a variety of high temperature applications. It is to be understood that methods other than resistance heaters may be used for producing substantially isothermal hot wall conditions for the process chamber; examples of some other methods of producing the substantially isothermal hot wall conditions have been presented in U.S. Pat. No. 6,331,212.

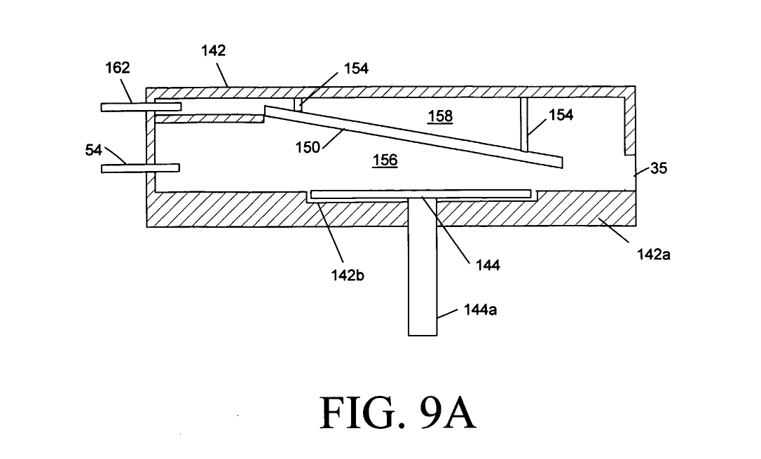

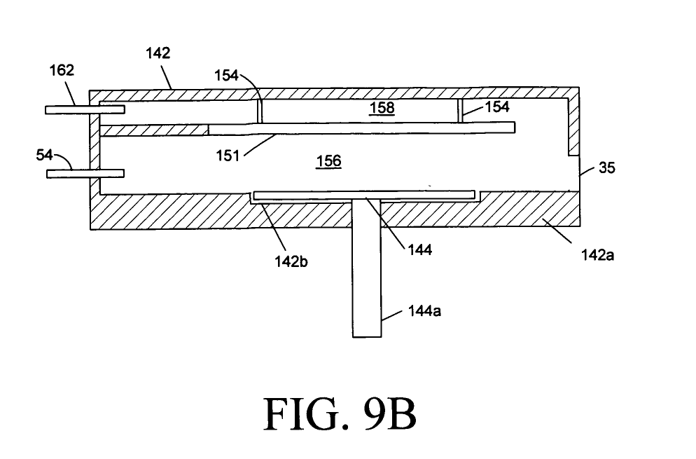

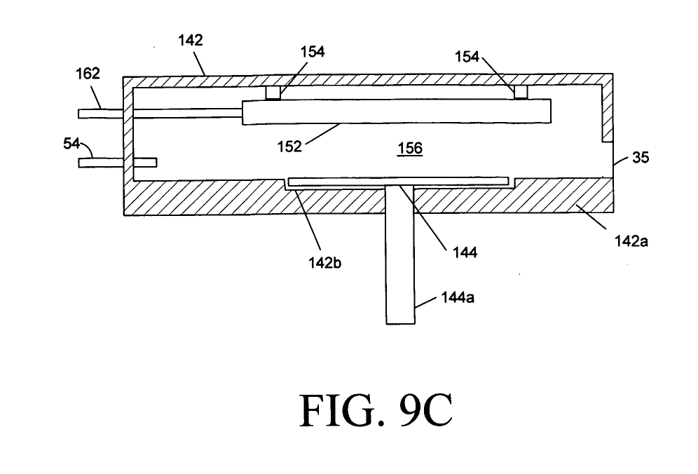

Reference is now made to FIG. 9A where there is shown another embodiment of a process chamber 142 according to the present invention. FIG. 9A shows process chamber 142 in a cross-section side view so as to show the interior of process chamber 142. Process chamber 142 includes a susceptor 144 connected with a stem 144a for coupling rotary motion from a rotary motion source, such as a motor (not shown in FIG. 9A), for rotating susceptor 144. The embodiment shown in FIG. 9A has stem 144a extending through the bottom surface of process chamber 142 so that the rotary motion coupling and motor can be located outside of process chamber 142. Process chamber 142 also has gas injectors such as gas injectors 54 connected for feeding gases as described above. Process chamber 142 also has an exhaust port 35 for gases to exit the process chamber. Process chamber 142 has a bottom surface 142a. Bottom surface 142a, optionally, includes a recessed area 142b so that susceptor 144 can be placed so as to provide a surface that is substantially level with the bottom surface of process chamber 142. It is to be understood that the recessed area is an option and is not required for all embodiments of the present invention.

FIG. 9A also shows process chamber 142 having a velocity gradient plate 150. Velocity gradient plate 150 is connected with process chamber 30. Preferably, velocity gradient plate 150 is substantially rigid and is substantially inert to the process gas. Velocity gradient plate 150 is arranged adjacent to susceptor 144 so as to define one side of a channel for process gas flow over the wafer supporting surface of susceptor 144, such that the cross-sectional area for the channel decreases in the direction of the process gas flow in response to perpendicular distance variations between velocity gradient plate 150 and the wafer holding surface of susceptor 144. Velocity gradient plate 150 is arranged so that the volume of process chamber 142 above susceptor 144 is divided into two parts. One part is volume 156 located between the surface of susceptor 144 and velocity gradient plate 150. The second part is volume 158 located between velocity gradient plate 150 and the top surface of process chamber 142.

In a preferred embodiment, velocity gradient plate 150 has a plurality of gas distribution holes so as to allow a gas flow to occur from volume 158 to volume 156. It is to be understood that having velocity gradient plate 150 configured with holes for distributing gas is an optional configuration; it is not required for all embodiments of the present invention.

In a preferred embodiment of the present invention, velocity gradient plate 150 is configured to perform as a showerhead for distributing process gas over a wafer held on susceptor 144. For such embodiments, the velocity gradient plate is substantially rigid and substantially inert to the process gas. The velocity gradient plate is arranged adjacent to the susceptor so as to define one side of a channel for a process gas flow over the wafer supporting surface of the susceptor so that the cross-sectional area for the channel decreases in the direction of the process gas flow in response to distance variations between the velocity gradient plate and the wafer holding surface of the susceptor. The velocity gradient plate is arranged so as to form a first volume comprising the channel located between the wafer holding surface of the susceptor and the velocity gradient plate and a second volume located between the velocity gradient plate and the top surface of the process chamber. The embodiment further includes at least one gas source connection with the second volume so as to provide gas to the second volume so that at least part of the gas from the at least one gas source connection flows through the showerhead velocity gradient plate into the first volume.

For some embodiments of the present invention, velocity gradient plate 150 may have a multiplicity of holes for gas flow. Furthermore, the size and arrangement of holes can be selected so as to provide a desired gas flow pattern along the surface of the wafer. To provide a gas flow for passing through velocity gradient plate 150, the embodiment shown in FIG. 9A includes gas injectors 162 coupled with at least one gas source connection so as to provide gas to volume 158 so that at least part of the gas from the at least one gas source connection flows through a showerhead configuration of velocity gradient plate 150 into volume 156. Process chamber 142 also includes a flow channel for directing gases from gas injectors 162 to volume 158 from which at least part of the gases from gas injectors 162 flow through the holes in velocity gradient plate 150 into volume 156. Preferably, for applications of growing doped silicon, gases from gas injectors 162 comprise hydrogen or a mixture of hydrogen and a dopant. It is to be understood that gases other than hydrogen, such as an inert gas like argon and helium, can be used. Also, it is to be understood that embodiments of the present invention can be used for applications other than growing doped silicon. As some examples, embodiments of the present invention can be configured for growing materials such as gallium nitride, gallium arsenide, and silicon germanium.

Reference is now made to FIG. 9B where there is shown another embodiment of the present invention. FIG. 9B shows a process chamber 142 that is essentially the same as the process chamber 142 described for FIG. 9A with the exception that the embodiment shown in FIG. 9B includes a parallel plate 151 instead of velocity gradient plate 150. Parallel plate 151 has the same properties as the velocity gradient plate except that parallel plate 151 is held in the process chamber so as to be parallel to the surface of the substrate. Unlike velocity gradient plate 150, plate 151 is substantially parallel to the surface of susceptor 144 so that a velocity gradient is substantially not produced by gas flow between plate 154 and susceptor 144. Plate 151 is configured so as to have a plurality of holes for allowing gas to flow from volume 158 into volume 156 substantially as described for the embodiment shown in FIG. 9A so as to provide a showerhead flow of gas over the surface of the substrate.

Some embodiments of the present invention use a velocity gradient plate configured as a showerhead or a parallel plate configured as a showerhead as described supra. Alternatively, another embodiment of the present invention includes a showerhead such as showerheads typically used for semiconductor wafer processing. In other words, a showerhead that includes an enclosure having a surface having a multiplicity of holes for directing a shower of flowing gas over a workpiece such as a semiconductor wafer. The showerhead is disposed within the process chamber. The showerhead is substantially rigid and substantially inert to the process gas. In one embodiment, the showerhead is arranged adjacent to the susceptor so as to define one side of a channel for a process gas flow over the wafer supporting surface of the susceptor so that the cross-sectional area for the channel decreases in the direction of the process gas flow in response to distance variations between the showerhead and the wafer holding surface of the susceptor. The embodiment further includes at least one gas source connection with the enclosure of the showerhead so that at least part of the gas from the at least one gas source connection flows through the showerhead toward the substrate. In another embodiment, the showerhead is held substantially parallel to the wafer supporting surface so as to not create a velocity gradient for gas flowing between the showerhead and the wafer supporting surface of the susceptor.

Reference is now made to FIG. 9C where there is shown another embodiment of the present invention. FIG. 9C shows a process chamber 142 that is substantially the same as that described for the embodiment presented for FIG. 9B with the exception that the embodiment shown in FIG. 9C includes a showerhead 152 instead of plate 151. Showerhead 152 is disposed opposite susceptor 144 so as to provide a showerhead distribution of gases over susceptor 144. Showerhead 152 is substantially parallel to the surface of susceptor 144.

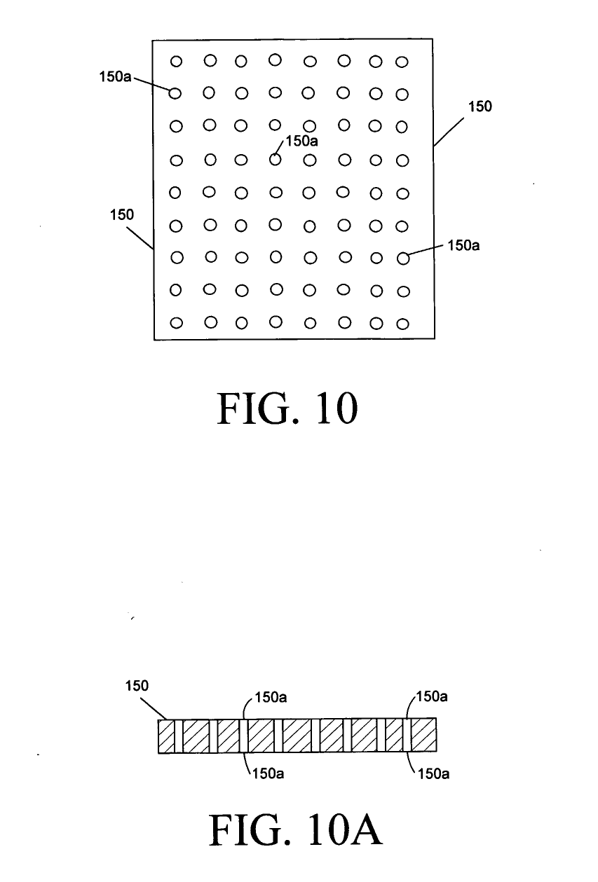

Reference is now made to FIG. 10 where there is shown a top view of a velocity gradient plate 150 according to one embodiment of the present invention. Velocity gradient plate 150 is a substantially rigid plate of a material suitable for use in a process chamber such as that for processing semiconductor wafers. Velocity gradient plate 150 has holes 150a for providing a gas flow through velocity gradient plate 150 as described supra. FIG. 10A shows a cross-section side view of velocity gradient plate 150. Holes 150a are shown passing from one side of plate 150 through to the opposite side of plate 150.

Preferably, velocity gradient plate 150 includes a refractory material. Examples of materials that can be used in velocity gradient plate 150 include materials such as quartz, silicon carbide, silicon carbide coated graphite, and ceramics. For silicon epitaxial growth applications, a preferred material for velocity gradient plate 150 is silicon carbide. More specifically, preferred embodiments of the present invention have silicon carbide as the surface material for velocity gradient plate 150, particularly those surfaces that are exposed to reactive process gases.

Velocity gradient plate 150 causes the process gas to have improved mass transfer characteristics as the process gas flows over the wafer. For applications involving processes such as deposition, epitaxial growth, and other applications requiring reactants in the process gas, the improved mass transfer characteristics help to compensate for depletion of reactants in the process gas. The reduction of depletion affects improves uniformity of deposited layer properties such as thickness uniformity, composition uniformity, dopant uniformity, optical properties, and electrical properties. Velocity gradient plate 150 further improves the gas flow characteristics above the wafer by providing what can be considered a blanket of gas to reduce the expansion of reactive gases flowing above the wafer. This makes it possible to generate a thinner boundary layer of reactive gases above the wafer. For some applications, the thinner boundary layer can produce higher deposition rates. Another potential benefit of providing a doped gas flow through velocity gradient plate 150 is that the uniformity of dopant distribution in a deposited layer can be further improved for some applications.

In another embodiment, velocity gradient plate 150 is movably connected with process chamber 142 so that the distance between velocity gradient plate 150 and susceptor 144 can be adjusted as another process parameter. Preferably, the distance between velocity gradient plate 150 and susceptor 144 can be adjusted and the angle between velocity gradient plate 150 and susceptor 144 can be adjusted. As an example, velocity gradient plate connector 154 suspends velocity gradient plate 150 from the top of process chamber 142. The length of connector 154 can be varied so as to change the position of velocity gradient plate 150 with respect to susceptor 144.

It is to be understood that the velocity gradient for embodiments of the present invention can be created by holding the velocity gradient plate, the showerhead velocity gradient plate, or the substrate holding surface at an angle suitable for producing a velocity gradient.

The velocity gradient plate configured as a showerhead, parallel plate configured as a showerhead, and the showerhead have holes for providing a showerhead flow as stated supra. In some preferred embodiments, the holes are a plurality of holes sized and arranged so as to be capable of producing a predetermined gas flow pattern over the substrate or wafer. The gas flow pattern is selected to provide desired results for thickness and composition uniformity for the process.

Embodiments of the present invention also include methods and apparatus for growing layers of materials such as elemental materials, compounds, compound semiconductors, and compound dielectric materials. In preferred embodiments for compound semiconductor applications, at least one of the individual gas injectors is connected so as to provide a flow of a gas comprising at least one of the elements boron, aluminum, gallium, indium, carbon, silicon, germanium, tin, lead, nitrogen, phosphorus, arsenic, antimony, sulfur, selenium, tellurium, mercury, cadmium, and zinc. In the preferred embodiment, a least one gas source connection is made to provide a gas flow to the back of the velocity gradient plate configured as a showerhead or a showerhead. The at least one gas source connection is connected so as to provide a flow of a gas or gas mixture such as hydrogen; an inert gas; hydrogen mixed with a dopant; or an inert gas mixed with a dopant.

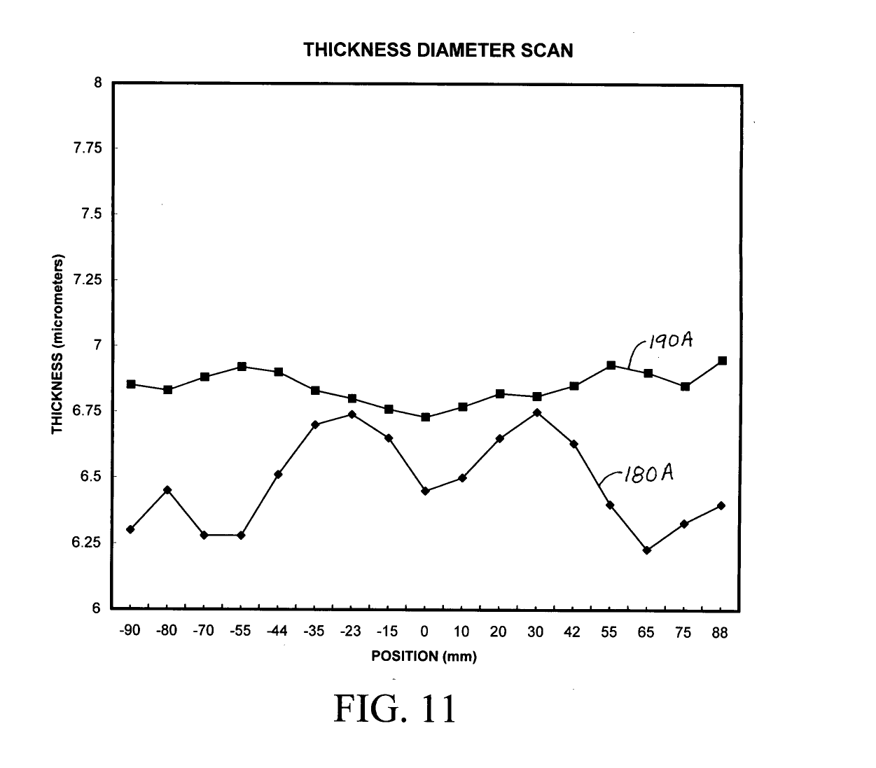

Reference is now made to FIG. 11 where there is shown a Thickness Diameter Scan for epitaxial layers of doped silicon deposited on to the surface of silicon wafers (200 mm diameter). The graph shows two sets of data. A first set of data 180A shows the thickness uniformity that is obtained when the gas composition and flow rates through all of the injectors are the same. A second set of data 190A shows the thickness uniformity that is obtained when the gas composition and flow rates through each of the injectors are adjusted for each injector according to embodiments of the present invention.

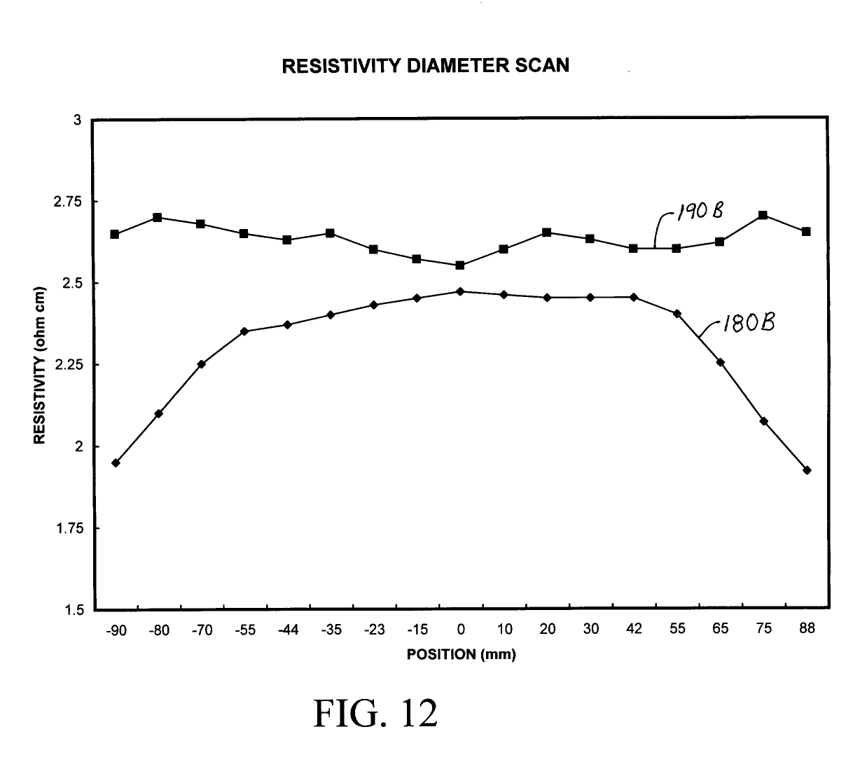

Reference is now made to FIG. 12 where there is shown a Resistivity Diameter Scan for the epitaxial layers of doped silicon described in FIG. 11. The graph shows two sets of data. A first set of data 180B shows the resistivity uniformity that is obtained when the gas composition and flow rates through all of the injectors are the same. A second set of data 190B shows the resistivity uniformity that is obtained when the gas composition and flow rates through each of the injectors are adjusted for each injector according to embodiments of the present invention. It is to be understood that the results presented in FIG. 11 and FIG. 12 do not necessarily represent optimized results.

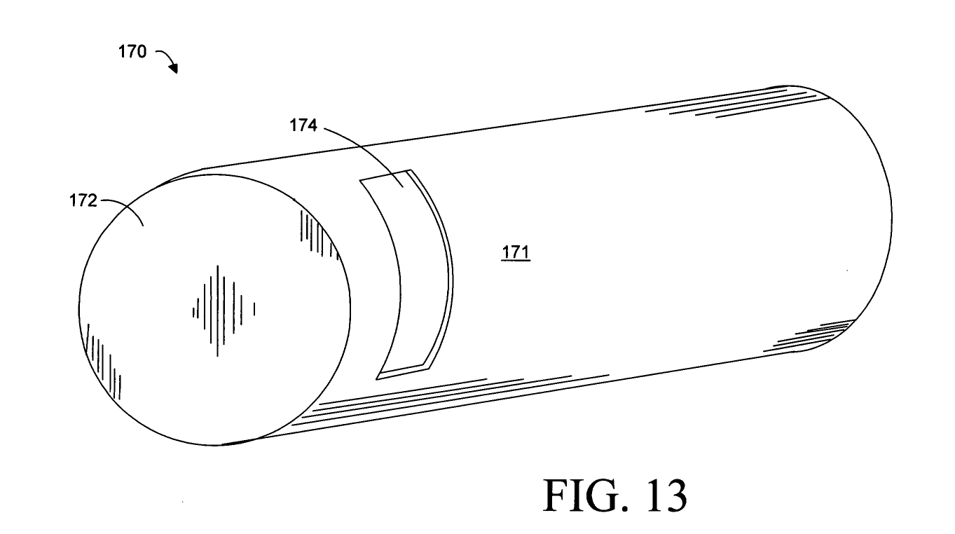

Reference is now made to FIG. 13 where there is shown a magnified view of a configuration for a gas injector for another embodiment of the present invention. FIG. 13 shows gas injector 170 comprising a gas conduit such as a gas flow tube having a sidewall 171 and a blanked end 172. Sidewall 171 has a hole such as a slot 174 configured so as to allow gases to exit gas injector 170. Other embodiments of the present invention include any of the process chambers as described in FIG. 1, FIG. 2A, FIG. 2B, FIG. 3, FIG. 4A, FIG. 4B, FIG. 5, FIG. 6A, FIG. 6B, FIG. 7, FIG. 8, FIG. 9A, FIG. 9B, and FIG. 9C configured with one or more of the gas injectors configured substantially as gas injector 170.

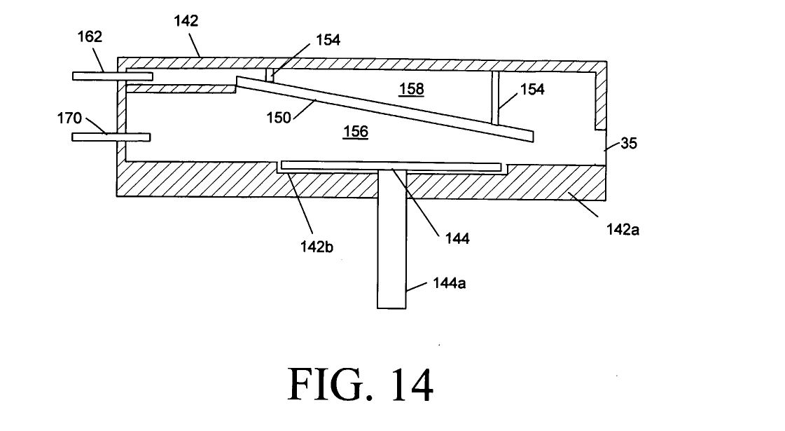

Reference is now made to FIG. 14 where there is shown a cross-section side view of a process chamber 142 substantially the same as that described for FIG. 9A. The difference between the embodiment shown in FIG. 9A and the embodiment shown in FIG. 14 is that the embodiment shown in FIG. 14 includes a gas injector 170 substantially as described for FIG. 13 as a replacement for one or more of the gas injectors 54 used for the embodiment in FIG. 9A.

An embodiment of the present invention includes an apparatus for depositing a layer of material from a gas source onto a substrate for manufacturing electronic devices. The apparatus comprises a substantially isothermal hot wall process chamber having a gas exhaust port and at least one gas injector connected with the process chamber. The apparatus also includes a susceptor disposed in the process chamber so as to hold the substrate between the at least one gas injector and the exhaust port. The at least one gas injector is positioned near the edge of the wafer. The injector is configured so that the gas flowing from the injector is impinged upon a hot surface in the process chamber before the gas gets to the susceptor.

In another embodiment, the gas injectors comprise a gas flow tube having a closed end proximate the susceptor. The tube has a hole in the sidewall of the tube near the closed end of the tube. The hole is configured for directing the gas flow perpendicularly to the axis of the tube so that the gas is impinged upon a hot surface in the process chamber before the gas gets to the susceptor.

In still another embodiment, the gas injector comprises a gas flow tube having a closed end proximate the substrate holder. The tube has a slot formed in the sidewall of the tube for directing the gas flow perpendicularly to the axis of the tube so that the gas is impinged upon a hot surface in the process chamber before the gas gets to the susceptor.

Another aspect of the present invention includes a method of depositing a uniform layer on a substrate. In one embodiment, the method involves depositing a uniform layer on a semiconductor wafer. The method includes the step of providing a plurality of gas flow streams across the surface of the wafer so that the gas flow is substantially parallel to the surface of the wafer and each flow stream is directed toward a specified region over the surface of the wafer. Preferably, the gas flow streams are substantially coplanar. The gas flow streams may be a single component gas or a gas mixture for depositing the layer. The method further includes the step of providing substantially independent temperature control for each of the gas flow streams for the specified region over the surface of the wafer. Another step and the method includes using a combination of flow rates, gas compositions, and temperatures independently controlled for each of the gas streams so as to deposit the uniform layer. In other words, producing a layer having high uniformity in terms of thickness and composition includes using a combination of gas flow rates, gas composition, and temperatures that interact together so as to produce an optimum or desired uniformity.

As a further embodiment of the method, the plurality of gas flow streams is provided with a plurality of gas injectors connected with enough mass flow controllers so as to independently control the gas flow rates and gas compositions for each of the gas flow streams. Preferably, the independent temperature control for each of the gas flow streams is provided with a plurality of heating elements so that at least one heating element is positioned for controlling the temperature for each of the gas flow streams.

The method according to embodiments of the present invention may include the use of a variety of process gases such as those described above. The gases used for the method will depend on the material to be deposited. In a preferred method, the gas flow streams comprise gas selected from the group consisting of silicon source gas, dopant gas, and hydrogen. Preferred embodiments of the present invention include methods for depositing an epitaxial layer of silicon on a silicon wafer. Alternatively, embodiments of the present invention include methods for depositing epitaxial layers of a compound semiconductor. As still another option, methods according to the present invention include depositing layers that comprise dielectric materials.

Clearly, embodiments of the present invention can be used for a wide variety of elevated temperature processes such as those for semiconductor device fabrication. Changes in the selected process gases allow embodiments of the present invention to be suitable for substrate processing steps such as depositing compound semiconductors such as silicon germanium, gallium arsenide, indium phosphide, gallium arsenide, indium antimonide, mercury cadmium telluride, gallium nitride, and silicon carbide.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

While there have been described and illustrated specific embodiments of the invention, it will be clear that variations in the details of the embodiments specifically illustrated and described may be made without departing from the true spirit and scope of the invention as defined in the appended claims and their legal equivalents.

What is claimed is:

1. An apparatus for depositing a layer of material from a gas source onto a wafer for manufacturing electronic devices, the apparatus comprising:
a process chamber having a top surface, a bottom surface, and an exhaust port for gases to exit the process chamber;
a susceptor having a wafer holding surface disposed in the process chamber;
a plurality of gas injectors connected to the process chamber so as to provide a flow of process gas substantially parallel to the wafer holding surface;
a velocity gradient plate configured as a showerhead disposed within the process chamber, the velocity gradient plate being substantially rigid and substantially inert to the process gas, the velocity gradient plate being arranged adjacent to the susceptor so as to define one side of a channel for a process gas flow over the wafer supporting surface of the susceptor so that the cross-sectional area for the channel decreases in the direction of the process gas flow in response to distance variations between the velocity gradient plate and the wafer holding surface of the susceptor, the velocity gradient plate being arranged so as to form a first volume comprising the channel located between the wafer holding surface of the susceptor and the velocity gradient plate and a second volume located between the velocity gradient plate and the top surface of the process chamber; and
at least one gas source connection with the second volume so as to provide gas to the second volume so that at least part of the gas from the at least one gas source connection flows through the showerhead velocity gradient plate into the first volume.

2. The apparatus of claim 1 wherein the velocity gradient plate has a plurality of holes sized and arranged so as to be capable of producing a predetermined gas flow pattern over the wafer.

3. The apparatus of claim 1 wherein the susceptor is rotatably coupled to the process chamber to allow rotation of the wafer during processing.

4. The apparatus of claim 1 wherein the plurality of gas injectors comprises individual gas injectors directing a gas flow to a selected area over the wafer holder surface and parallel to the wafer holder surface.

5. The apparatus of claim 1 wherein the plurality of gas injectors comprises individual gas injectors directing a gas flow to a selected area over the wafer holder surface and substantially parallel to the wafer holder surface; the apparatus further comprising a gas flow control system comprising a plurality of mass flow controllers wherein each of the individual gas injectors is connected with at least one dedicated mass flow controller so that each gas injector is capable of providing an independently controlled gas flow rate.

6. The apparatus of claim 1 wherein the plurality of gas injectors comprises individual gas injectors directing a gas flow to a selected area over the wafer holder surface and substantially parallel to the wafer holder surface; the apparatus further comprising a gas flow control system comprising a plurality of mass flow controllers wherein each of the individual gas injectors is connected with at least one dedicated mass flow controller so that each gas injector is capable of providing an independently controlled gas flow rate and an independently controlled inlet gas composition.

7. The apparatus of claim 1 wherein the process chamber is configured to function as a hot wall process chamber.

8. The apparatus of claim 3 wherein the process chamber is configured to function as a substantially isothermal hot wall process chamber.

9. The apparatus of claim 3 wherein the process chamber and substrate holder are configured to maintain the substrate at a substantially isothermal temperature during processing.

10. The apparatus of claim 6 wherein at least one of the individual gas injectors is connected to a gas supply to provide a flow of:
a silicon compound and hydrogen, or
a silicon compound, a dopant, and hydrogen;
and wherein at least one of the individual gas injectors is connected to a gas supply to provide a flow of:
hydrogen, or
hydrogen mixed with a dopant;
and wherein the at least one gas source connection is connected to a gas supply to provide a flow of:
hydrogen, or
hydrogen mixed with a dopant.

11. The apparatus of claim 6 wherein the material comprises a compound semiconductor and at least one of the individual gas injectors is connected so as to provide a flow of a gas comprising at least one of the elements boron, aluminum, gallium, indium, carbon, silicon, germanium, tin, lead, nitrogen, phosphorus, arsenic, antimony, sulfur, selenium, tellurium, mercury, cadmium, and zinc;
and wherein the at least one gas source connection is connected so as to provide a flow of:
hydrogen, or
hydrogen mixed with a dopant.

12. An apparatus for depositing a layer of material from a gas source onto a wafer for manufacturing electronic devices, the apparatus comprising:
a hot wall substantially isothermal process chamber having a gas exhaust port;
a susceptor having a wafer holding surface disposed in the process chamber, the susceptor being rotatably coupled so as to allow rotation of the wafer;
a plurality of gas injectors connected to the process chamber so as to provide a spatially distributed flow of gas in a plane substantially parallel to the wafer holding surface, the susceptor being disposed between the plurality of gas injectors and the gas exhaust port, the plurality of gas injectors being positioned along the edge of the wafer holding surface, each of the gas injectors of the plurality of gas injectors being spaced so that each of the gas injectors provides a flow directed toward a specified region of the area above the wafer holding surface;
a gas flow control system for controlling the flow of at least two dissimilar process gases, the gas flow control system being connected with the plurality of gas injectors, the gas flow control system being capable of at least one of:
A. independently controlling the flow rate of each of the process gases applied to each of the gas injectors of the plurality of gas injectors and
B. independently controlling the composition of the process gases applied to each of the gas injectors of the plurality of gas injectors; and
a plurality of heating elements disposed about the process chamber so as to allow substantially independent temperature control of the process chamber surfaces for the specified region of the area above the wafer holding surface for each of the gas injectors.

13. The apparatus of claim 12 further comprising a temperature control system configured for substantially independent control of the temperature of different regions of the process chamber surface.

14. The apparatus of claim 12 further comprising a temperature control system configured for substantially independent control of the temperature of each of the heating elements so as to control the temperatures of different regions of the process chamber surface.

15. The apparatus of claim 12 further comprising a temperature control system comprising a plurality of temperature sensors, the temperature sensors being placed so as to provide temperature measurements for controlling the temperatures of different regions of the process chamber surface.

16. The apparatus of claim 12 further comprising a temperature control system comprising a plurality of temperature sensors, the temperature sensors being placed so as to provide temperature measurements for controlling the temperatures of each of the heating elements.

17. The apparatus of claim 12 further comprising a baffle disposed in front of the plurality of gas injectors so that gases from the plurality of gas injectors impinge on the baffle before reaching the susceptor; the baffle comprising a substantially rigid plate of a refractory material.

18. The apparatus of claim 12 wherein the plurality of gas injectors comprises multiple alternating pairs of gas injectors; each pair of gas injectors being connected with the gas flow control system so as to have:
a first injector configured to provide a flow mixture of hydrogen and a silicon source; and
a second injector configured to provide a flow mixture of hydrogen and a dopant.

19. The apparatus of claim 12 wherein the plurality of gas injectors comprises multiple alternating pairs of gas injectors; each pair of gas injectors being connected with the gas flow control system so as to have:
a first injector configured to provide a flow mixture of hydrogen, a silicon source, and a dopant; and
a second injector configured to provide a flow mixture of hydrogen and a dopant.

20. The apparatus of claim 12 wherein one of the process gases comprises at least one of silane, monochlorosilane, dichlorosilane, trichlorosilane, and tetrachlorosilane.

21. The apparatus of claim 12 wherein one of the process gases comprises at least one of the elements boron, aluminum, gallium, indium, carbon, silicon, germanium, tin, lead, nitrogen, phosphorus, arsenic, antimony, sulfur, selenium, tellurium, mercury, cadmium, and zinc.

22. The apparatus of claim 12 wherein the gas flow control system includes gas flow conduits, valves, and mass flow controllers so that the mass flows for each of the gases provided to the process chamber can be independently controlled.

23. The apparatus of claim 12 wherein the plurality of gas injectors comprises concentric gas flow tubes with an inner tube for carrying an inner gas flow mixture and an outer tube for carrying an outer gas flow mixture.

24. The apparatus of claim 12 wherein the plurality of gas injectors comprises concentric gas flow tubes with an inner tube for carrying an inner gas flow mixture and an outer tube for carrying an outer gas flow mixture, the concentric gas flow tubes being connected with the gas flow control system so that the inner gas flow mixture comprises a flow mixture of hydrogen plus a silicon source plus a dopant, and the outer gas flow mixture comprises a flow mixture of hydrogen plus a dopant.

25. The apparatus of claim 12 wherein the plurality of gas injectors comprises concentric gas flow tubes with an inner tube for carrying an inner gas flow mixture and an outer tube for carrying an outer gas flow mixture and the tubes are mechanically held so that the openings for each of the tubes remain concentric.

26. The apparatus of claim 12 wherein the plurality of gas injectors comprises concentric gas flow tubes with an inner tube and an outer tube, the tubes being mechanically held so that the openings for each of the tubes remain concentric; the outer tube having dimples formed in the surface of the outer tube so as to make contact with the inner tube at three substantially equally spaced points around the circumference of the inner tube.

27. The apparatus of claim 12 wherein the plurality of gas injectors comprises at least one gas injector that includes concentric gas flow tubes with an inner tube for carrying an inner gas flow mixture and an outer tube for carrying a purge gas; the gas flow control system comprises a plurality of first mass flow controllers so as to have a separate first mass flow controller for each of the inner tubes and a plurality of second mass flow controllers so as to have a second mass flow controller for each of the inner tubes; the first mass flow controllers are configured so as to control the flow of a gas mixture of hydrogen plus dopant that feeds into a flow of a gas mixture of silicon source plus hydrogen; the second mass flow controllers are configured to control the flow of the gas mixture from the first mass flow controllers and the gas mixture of silicon source plus hydrogen; and the gas flow control system is connected with the outer tube of the gas injectors so as to provide a controlled flow of hydrogen to the outer tubes.

28. The apparatus of claim 12 wherein the plurality of gas injectors comprises at least one gas injector that includes concentric gas flow tubes with an inner tube for carrying an inner gas flow and an outer tube for carrying an outer gas flow; the gas flow control system comprises a plurality of first mass flow controllers so as to have a separate first mass flow controller for each of the inner tubes and a plurality of second mass flow controllers so as to have a second mass flow controller for each of the outer tubes; the first mass flow controllers are configured so as to control the flow of a gas mixture of hydrogen plus silicon source into the inner tubes; the second mass flow controllers are configured to control the flow of hydrogen plus dopant to the outer tubes.

29. The apparatus of claim 12 further comprising:
a velocity gradient plate disposed within the process chamber, the velocity gradient plate being substantially rigid and substantially inert to the process gas, the velocity gradient plate being arranged adjacent to the susceptor so as to define one side of a channel for the process gas flow over the wafer holding surface of the susceptor so that the cross-sectional area for the channel decreases in the direction of the process gas flow in response to distance variations between the velocity gradient plate and the wafer holding surface of the susceptor.

30. The apparatus of claim 12 further comprising:
a velocity gradient plate configured as a showerhead, the velocity gradient plate being disposed within the process chamber, the velocity gradient plate being substantially rigid and substantially inert to the process gas, the velocity gradient plate being arranged adjacent to the susceptor so as to define one side of a channel for the process gas flow over the wafer holding surface of the susceptor so that the cross-sectional area for the channel decreases in the direction of the process gas flow in response to distance variations between the velocity gradient plate and the wafer holding surface of the susceptor, the velocity gradient plate being arranged so as to form a first volume that includes the channel located between the wafer holding surface of the susceptor and the velocity gradient plate, and a second volume located between the velocity gradient plate and the top surface of the process chamber;
at least one gas source connection with the second volume so as to provide gas to the second volume so that at least part of the gas from the at least one gas source connection flows through the showerhead velocity gradient plate into the first volume.

31. An apparatus for depositing a layer of material from a gas source onto a substrate for manufacturing electronic devices, the apparatus comprising:
a substantially isothermal hot wall process chamber having a gas exhaust port;
at least one gas injector connected with the process chamber, the gas injector being connected so as to provide a flow of gas to the deposition surface of the substrate;
a susceptor disposed in the process chamber so as to hold the substrate between the gas injectors and the exhaust port;
the at least one gas injector being positioned near the edge of the wafer, the at least one gas injector being configured so that the gas flowing from the injectors is impinged upon a hot surface in the process chamber before the gas gets to the susceptor.

32. The apparatus of claim 31 wherein the gas injector comprises a gas flow tube, the tube having a closed end proximate the susceptor, the tube having a hole in the sidewall of the tube for directing the gas flow perpendicularly to the axis of the tube so that the gas is impinged upon the hot surface.

33. The apparatus of claim 31 wherein the gas injectors comprise a gas flow tube, the tube having a closed end proximate the susceptor, the tube having a slot formed in the sidewall of the tube for directing the gas flow perpendicularly to the axis of the tube so that the gas is impinged upon the hot surface.

34. The apparatus of claim 31 wherein the gas injectors comprise a gas flow tube, the tube having a closed end proximate the susceptor, the tube having a slot formed in the sidewall of the tube for directing the gas flow perpendicularly to the axis of the tube so that the gas is impinged upon the hot surface, the slot being oriented so as to direct a gas flow substantially perpendicularly to the surface of the substrate.

35. An apparatus for processing a wafer, the apparatus comprising:
a process chamber having a gas exhaust port;
a showerhead configured for providing a showerhead gas flow;
a susceptor having a wafer holding surface opposite the showerhead so as to receive the showerhead gas flow; and
a plurality of gas injectors arranged so as to be capable of providing a gas flow substantially parallel to and over the wafer holding surface from the plurality of gas injectors to the exhaust port.

36. The apparatus of claim 35, wherein the showerhead and the wafer holder surface are disposed at an angle so as to define a channel having a decreasing cross-sectional area so as to create a velocity gradient for gas flow through the channel.

37. The apparatus of claim 35 further comprising a gas flow control system so as to have independent control of flow rate and composition for each injector.

38. The apparatus of claim 35, wherein the showerhead and the wafer holder surface are disposed at an angle so as to define a channel having a decreasing cross-sectional area so as to create a velocity gradient for gas flow through the channel and further comprising a gas flow control system so as to have independent control of flow rate and composition for each injector.

39. The apparatus of claim 35 wherein at least one of the gas injectors comprises a gas flow tube, the tube having a blanked end proximate the susceptor, the tube having a hole in the sidewall of the tube for directing the gas flow perpendicularly to the axis of the tube so that the gas is impinged upon a hot surface be before reaching the susceptor.

40. A method of depositing a uniform layer on a semiconductor wafer, the method comprising the steps of:
providing a plurality of gas flow streams across the surface of the wafer so that the gas flow is substantially parallel to the surface of the wafer and each flow stream is directed toward a specified region over the surface of the wafer, the gas flow streams being substantially coplanar, the gas flow streams comprising a single gas or a gas mixture for depositing the layer;
providing substantially independent temperature control for each of the gas flow streams for the specified region over the surface of the wafer; and
using a combination of flow rates, gas compositions, and temperature independently controlled for each of the gas streams so as to deposit the uniform layer.

41. The method of claim 40 wherein the plurality of gas flow streams is provided with a plurality of gas injectors connected with enough mass flow controllers so as to independently control the gas flow rates and gas compositions for each of the gas flow streams; the independent temperature control for each of the gas flow streams is provided with a plurality of heating elements so that at least one heating element is positioned for controlling the temperature for each of the gas flow streams.

42. The method of claim 41 wherein the gas flow streams comprise gas selected from the group consisting of silicon source gas, dopant gas, and hydrogen.

43. The method of claim 41 wherein the layer comprises an epitaxial layer of silicon and the substrate comprises a silicon wafer.

44. The method of claim 41 wherein the layer comprises an epitaxial layer of a compound semiconductor.

45. The method of claim 41 wherein the layer comprises dielectric material.
